(19) United States
(12) Patent Application Publication
(10) Pub. No.: US 2023/0109286 A1
(43) Pub. Date: Apr. 6, 2023

(54) DISPLAY APPARATUS

(71) Applicant: SAMSUNG DISPLAY CO., LTD., Yongin-si (KR)

(72) Inventors: Seongjin Hwang, Yongin-si (KR); Kyungman Kim, Yongin-si (KR); Dawoon Kim, Yongin-si (KR); Sanghoon Kim, Yongin-si (KR); Sunghoon Kim, Yongin-si (KR); Seungho Kim, Yongin-si (KR); Yuri Kim, Yongin-si (KR); Minhoon Choi, Yongin-si (KR)

(21) Appl. No.: 17/851,549

(22) Filed: Jun. 28, 2022

(30) Foreign Application Priority Data
Oct. 6, 2021 (KR) 10-2021-0132691

(51) Int. Cl. H01L 51/52

(52) U.S. Cl. CPC H01L 51/524; H01L 27/3244

(57) ABSTRACT

A display apparatus includes a display panel that is foldable with respect to a folding axis, and a cover window disposed on the display panel and including a folding portion and a peripheral portion adjacent to the folding portion, wherein the cover window includes a first layer including a plurality of projection portions apart from each other in a first direction, a second layer partially concave to accommodate the projection portions and coupled to the projection portions with a gap therebetween, and a resin filled in the gap.

This application claims priority to Korean Patent Application No. 10-2021-0132691, filed on Oct. 6, 2021, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus including a cover window for alleviating stress during folding or bending.

### 2. Description of the Related Art

An electronic device, such as a smartphone, a digital camera, a notebook computer, a navigation device, a smart television, etc., that provides an image to a user, includes a display apparatus for displaying the image. A display apparatus may include a display panel for generating and displaying an image and a cover window arranged above the display panel for protecting the display panel.

Recently, display apparatuses have been used in various fields, and display apparatuses with reduced thickness and weight have extended a range of use thereof. Of late, flexible display panels have been developed. Each of components of the flexible display panel includes a flexible material, such as plastic, etc., so that the flexible display panel may be flexible.

The cover window in the flexible display panel may be desired to be rigid to protect the flexible display panel from external shocks and at the same time may be desired to be flexible. Various studies have been attempted to develop a cover window having such characteristics.

### SUMMARY

One or more embodiments provide a cover window and a display apparatus, in which the durability of a folding or bending area is enhanced, in order to solve various problems.

According to one or more embodiments, a display apparatus includes a display panel that is foldable with respect to a folding axis, and a cover window disposed on the display panel, where a folding portion and a peripheral portion adjacent to the folding portion are defined in the cover window. In such an embodiment, the cover window includes a first layer including a plurality of projection portions apart from each other in a first direction, a second layer partially concave to accommodate the plurality of projection portions and coupled to the projection portions with a gap therebetween, and a resin filled in the gap.

In an embodiment, a material included in the first layer may be different from a material included in the second layer.

In an embodiment, the plurality of projection portions may be disposed in the folding portion.

In an embodiment, each of the plurality of projection portions may have a width decreasing in a direction.

In an embodiment, the folding portion may have a radius of curvature when folded, and a length of an area in which the plurality of projection portions is disposed may be greater than pi (π) times the radius of curvature.

In an embodiment, the first layer, the second layer, and the resin may have a same refractive index as each other.

In an embodiment, the plurality of projection portions may be disposed through the second layer.

In an embodiment, a thickness of an area of the second layer, which accommodates the plurality of projection portions, may be less than or equal to a half of a thickness of an area of the second layer, which does not accommodate the plurality of projection portions.

In an embodiment, a thickness of an area of the first layer, in which the plurality of projection portions is disposed, may be less than a thickness of an area of the first layer, in which the plurality of projection portions is not disposed.

In an embodiment, the first layer may further include a concave portion, and the plurality of projection portions may project from the concave portion.

In an embodiment, a height of at least one selected from the plurality of projection portions may be greater than a thickness of the first layer.

In an embodiment, the plurality of projection portions may be disposed to interlock with the second layer.

In an embodiment, The second layer may further include an accommodation portion which accommodates the plurality of projection portions, and the gap may vary between the projection portions and the accommodation portion.

In an embodiment, the plurality of projection portions may be accommodated in a single accommodation portion.

In an embodiment, the resin may be disposed in a space between the plurality of projection portions.

In an embodiment, the second layer may include a groove in a surface opposite to a surface on which the plurality of projection portions is disposed.

In an embodiment, the groove may be disposed between the plurality of projection portions.

In an embodiment, the groove may be provided in plural, and a width of at least one of a plurality of grooves may be different from a width of another of the plurality of grooves.

In an embodiment, the grooves may be provided in plural, and a plurality of grooves may be symmetrical with respect to the folding axis.

According to one or more embodiments, a display apparatus includes a display panel which is foldable with respect to a folding axis, and a cover window disposed on the display panel, where a folding portion and a peripheral portion adjacent to the folding portion are defined in the cover window. In such an embodiment, the cover window includes a first layer including a projection portion projecting in a direction, and a second layer including an accommodation portion which accommodates the projection portion, and a distance between an outer surface of the projection portion and an inner surface of the accommodation portion in a direction vertical to the outer surface of the projection portion varies along the outer surface of the projection portion.

In an embodiment, a resin may be disposed between the projection portion and the accommodation portion.

In an embodiment, the distance may have a greatest value at a center of the projection portion.

In an embodiment, the projection portion may have a semi-circular cross-section when viewed vertically with respect to the folding axis.

According to one or more embodiments, a display apparatus includes a display panel that is foldable with respect to a folding axis, and a cover window disposed on the display panel, where a folding portion and a peripheral portion adjacent to the folding portion are defined in the cover window. In such an embodiment, the cover window includes a first layer including a plurality of projection patterns, and a second layer including a plurality of accommodation patterns which accommodates the plurality of projection patterns.

In an embodiment, one of the plurality of projection patterns or one of the plurality of accommodation patterns may be different from another of the plurality of projection patterns or another of the plurality of accommodation patterns.

In an embodiment, the plurality of projection patterns and the plurality of accommodation patterns may be disposed in the folding portion and the peripheral portion adjacent to the folding portion.

In an embodiment, the folding portion may be provided in plural, a plurality of folding portions may be disposed in a way such that the plurality of folding portions are apart from each other in a direction, and each of the plurality of projection patterns and each of the plurality of accommodation patterns may be disposed in each of the plurality of folding portions.

### BRIEF DESCRIPTION OF THE DRAWINGS

The above and other features of certain embodiments of the disclosure will be more apparent from the following description taken in conjunction with the accompanying drawings, in which:

FIGS. 1 and 2 are schematic perspective views of a display apparatus according to an embodiment;

FIG. 3 is a schematic cross-sectional view of a portion of a display apparatus according to an embodiment;

FIGS. 4 through 11 are cross-sectional views of a cover window according to an embodiment;

FIGS. 12 and 13 are cross-sectional views of a cover window according to an alternative embodiment;

FIGS. 14 through 16 are cross-sectional views of a cover window according to another alternative embodiment;

FIGS. 17 and 18 are perspective views of a display apparatus according to another alternative embodiment; and

FIGS. 19 through 21 are cross-sectional views of a cover window according to another alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In the drawings, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. Like reference numerals refer to like elements throughout, and any repetitive detailed description thereof may be omitted or simplified.

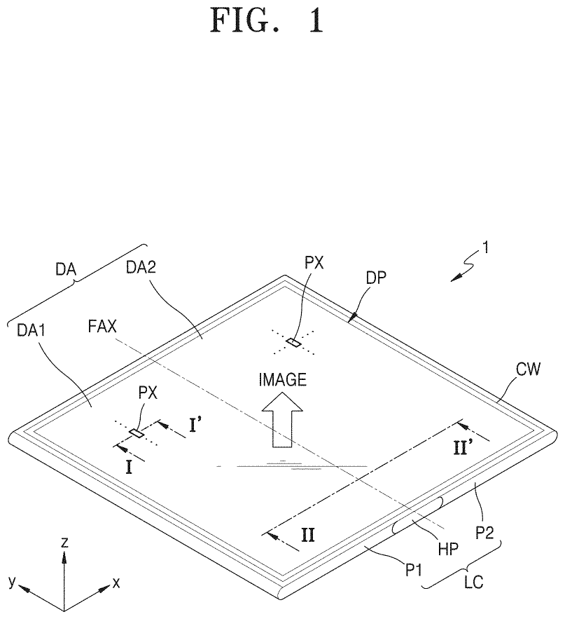

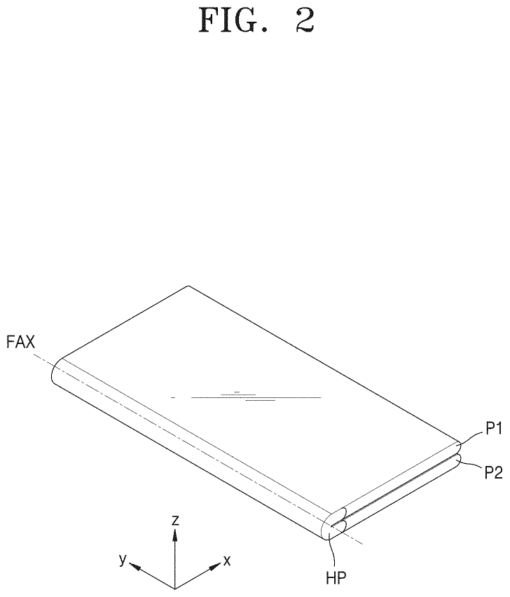

FIGS. 1 and 2 are schematic perspective views of a display apparatus 1 according to an embodiment. In detail, FIG. 1 illustrates the display apparatus 1 in an unfolded state, and FIG. 2 illustrates the display apparatus 1 in a folded state.

Referring to FIGS. 1 and 2, an embodiment of the display apparatus 1 may include a lower cover LC, a display panel DP, and a cover window CW.

The lower cover LC may include a first portion P1 and a second portion P2 supporting the display panel DP. The lower cover LC may be folded with respect to a folding axis FAX defined between the first portion P1 and the second portion P2 of the lower cover LC. According to an embodiment, the lower cover LC may further include a hinge portion HP, and the hinge portion HP may be disposed or provided between the first and second portions P1 and P2.

The display panel DP may include a display area DA. The display panel DP may provide an image through an array of a plurality of pixels PX arranged in the display area DA. Each pixel PX may be defined as an emission area for emitting light based on a light-emitting element electrically connected to a pixel circuit. The light-emitting element may include, for example, an organic light-emitting display. In an embodiment, each pixel PX may emit red, green, or blue light. Alternatively, each pixel PX may emit red, green, blue, or white light.

The display area DA may include a first display area DA1 and a second display area DA2 arranged at opposing sides of the folding axis FAX crossing the display area DA. The first display area DA1 and the second display area DA2 may be on the first portion P1 and the second portion P2 of the lower cover LC, respectively. The display panel DP may provide a first image and a second image by using light emitted from the plurality of pixels PX arranged in the first display area DA1 and the second display area DA2. According to an embodiment, the first and second images may be portions of an image provided by the display area DA of the display panel DP. Alternatively, the display panel DP may provide the first and second images that are separate images.

The display panel DP may be folded with respect to the folding axis FAX.

According to an embodiment, when the display panel DP is folded, the first display area DA1 and the second display area DA2 of the display panel DP may face each other. According to an alternative embodiment, when the display panel DP is folded, the first display area DA1 and the second display area DA2 of the display panel DP may respectively face directions opposite to each other.

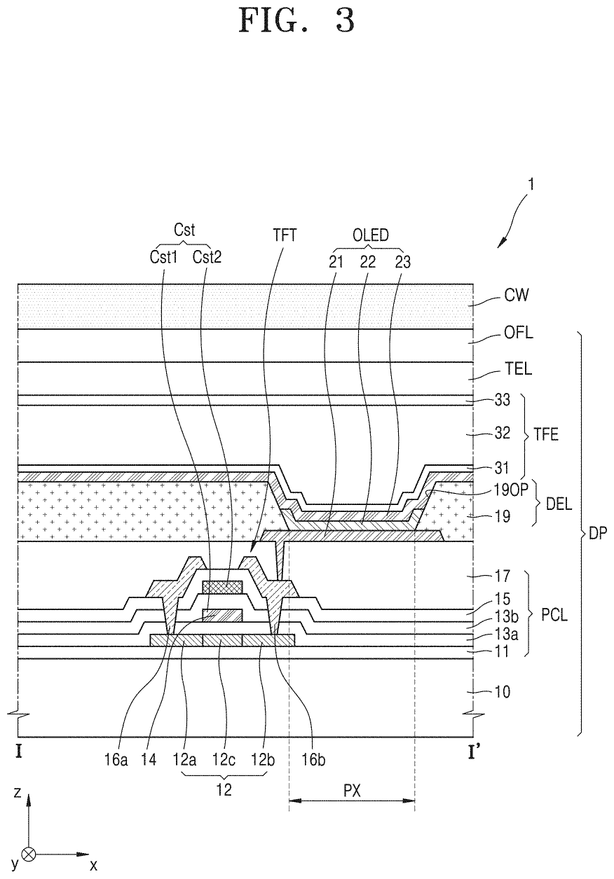

In an embodiment, the display panel DP may be in-folded or out-folded with respect to the folding axis FAX. Here, in-folding may denote folding of the display panel DP in a +z direction with respect to the folding axis FAX, and out-folding may denote folding of the display panel DP in a −z direction with respect to the folding axis FAX. In such an embodiment, in-folding may denote the display panel DP configured to be folded in a way such that upper surfaces of the cover window CW face each other, and out-folding may denote the display panel DP configured to be folded in a way such that lower surfaces of the cover window CW face each other. Here, the lower surface of the cover window CW may be a surface closer to a substrate 10 (FIG. 3) in a z direction than the upper surface of the cover window CW.

FIGS. 1 and 2 illustrate an embodiment in which the folding axis FAX extends in a y direction. However, one or more embodiments are not limited thereto. According to an alternative embodiment, the folding axis FAX may extend in an x direction crossing the y direction. Alternatively, the folding axis FAX may extend in a direction crossing the x direction and the y direction on an x-y plane.

Also, FIGS. 1 and 2 illustrate an embodiment in which a single folding axis FAX is defined. However, one or more embodiments are not limited thereto. According to an alternative embodiment, the display panel DP may be folded with respect to two folding axes crossing the display area DA. In an embodiment, for example, where the display panel DP is folded or foldable with respect to the two folding axes FAX, the display panel DP may be in-folded with respect to one folding axis FAX and may be out-folded with respect to the other folding axis FAX. Alternatively, the display panel DP may be in-folded with respect to both of the two folding axes FAX or out-folded with respect to both of the two folding axes FAX. However, one or more embodiments are not limited thereto. According to an alternative embodiment, the display panel DP may be folded or foldable with respect to a plurality of folding axes FAX crossing the display area DA. In such an embodiment, the display panel DP may be in-folded or out-folded with respect to each folding axis FAX.

The cover window CW may be arranged on the display panel DP and may cover the display panel DP. The cover window CW may be folded or bent via an external force without cracks, etc. occurring. When the display panel DP is folded with respect to the folding axis FAX, the cover window CW may be folded together with the display panel DP and may cover the display panel DP.

FIG. 3 is a schematic cross-sectional view of a portion of the display apparatus 1 according to an embodiment. FIG. 3 may correspond to a cross-section taken along line I-I′ of FIG. 1.

Referring to FIG. 3, an embodiment of the display panel DP may include the substrate 10, a pixel circuit layer PCL, a display element layer DEL, a thin-film encapsulation layer TFE, a touch electrode layer TEL, and an optical functional layer OFL that are stacked.

In an embodiment, the substrate 10 may include glass or a polymer resin. In such an embodiment, the polymer resin may include at least one selected from polyether sulfone, polyarylate, polyether imide, polyethylene naphthalate, polyethylene terephthalate, polyphenylene sulfide, polyimide, polycarbonate, cellulose triacetate, and cellulose acetate propionate.

The pixel circuit layer PCL may be arranged or disposed on the substrate 10. FIG. 3 illustrates an embodiment where the pixel circuit layer PCL includes a thin-film transistor TFT, and further includes a buffer layer 11, a first insulating layer 13a, a second insulating layer 13b, a third insulating layer 15, and a planarization layer 17 arranged below or/and above components of the thin-film transistor TFT.

The buffer layer 11 may reduce or block penetration of impurities, moisture, or external materials from below the substrate 10 and may provide a planarized surface to the substrate 10. The buffer layer 11 may include an inorganic insulating material, such as silicon nitride, silicon oxynitride or silicon oxide, and may have a single layer structure or a multilayer structure, each layer therein including at least one selected from the inorganic insulating materials described above.

The thin-film transistor TFT on the buffer layer 11 may include a semiconductor layer 12, and the semiconductor layer 12 may include polysilicon. Alternatively, the semiconductor layer 12 may include amorphous silicon, an oxide semiconductor, an organic semiconductor, or the like. The semiconductor layer 12 may include a channel area 12c, and a drain area 12a and a source area 12b at both sides of the channel area 12c. A gate electrode 14 may overlap the channel area 12c.

The gate electrode 14 may include a low-resistance metal material. The gate electrode 14 may include a conductive material including Mo, Al, Cu, Ti, etc. and may have a single layer structure or a multilayer structure, each layer therein including at least one selected from the conductive materials described above.

The first insulating layer 13a may be arranged or disposed between the semiconductor layer 12 and the gate electrode 14. The first insulating layer 13a may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Here, ZnO may include zinc oxide (ZnO) and/or zinc peroxide (ZnO₂).

The second insulating layer 13b may cover the gate electrode 14. The second insulating layer 13b may include an inorganic insulating material, such as SiO₂, SiNₓ, SiON, Al₂O₃, TiO₂, Ta₂O₅, HfO₂, or ZnOₓ. Here, ZnOₓ may include ZnO and/or ZnO₂.

An upper electrode Cst2 of a storage capacitor Cst may be arranged or disposed on the second insulating layer 13b. The upper electrode Cst2 may at least partially overlap the gate electrode 14 therebelow. The gate electrode 14 and the upper electrode Cst2 overlapping each other with the second insulating layer 13b therebetween may be included in the storage capacitor Cst. In such an embodiment, the gate electrode 14 may function as a lower electrode Cst1 of the storage capacitor Cst.

In an embodiment, as described above, the storage capacitor Cst and the thin-film transistor TFT may overlap each other. Alternatively, the storage capacitor Cst may not overlap the thin-film transistor TFT. In such an embodiment, the lower electrode Cst1 of the storage capacitor Cst may be a component separate from the gate electrode 14 and may be apart from the gate electrode 14.

The upper electrode Cst2 may include Al, Pt, Pd, Ag, Mg, Au, Ni, Nd, Ir, Cr, Ca, Mo, Ti, W, and/or Cu and may have a single layer structure or a multilayer structure, each layer therein including at least one selected from the materials described above.

The third insulating layer 15 may cover the upper electrode Cst2. The third insulating layer 15 may include an inorganic insulating material, such as SiO₂, SiNₓ, SiON, Al₂O₃, TiO₂, Ta₂O₅, HfO₂, or ZnOₓ. Here, ZnO, may include ZnO and/or ZnO₂. The third insulating layer 15 may have a single layer structure or a multilayer structure, each layer therein including at least one selected from the inorganic insulating materials described above.

Each of a drain electrode 16a and a source electrode 16b may be on the third insulating layer 15. The drain electrode 16a and the source electrode 16b may be connected to the drain area 12a and the source area 12b, respectively, through contact holes of insulating layers below the drain electrode 16a and the source electrode 16b. The drain electrode 16a and the source electrode 16b may include a highly conductive material. The drain electrode 16a and the source electrode 16b may include a conductive material including Mo, Al, Cu, Ti, etc. and may have a single layer structure or a multilayer structure. According to an embodiment, the drain electrode 16a and the source electrode 16b may have a multilayer structure, e.g., a Ti/Al/Ti structure.

The planarization layer 17 may include an organic insulating material. The planarization layer 17 may include an organic insulating material, such as a general-purpose polymer such as polymethylmethacrylate (“PMMA”) or polystyrene (“PS”), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be arranged or disposed on the pixel circuit layer PCL having the structures described above. The display element layer DEL may include an organic light-emitting diode OLED as the light-emitting element, and the organic light-emitting diode OLED may include a pixel electrode 21, an emission layer 22, and a common electrode 23 that are stacked one on another. The pixel electrode 21 of the organic light-emitting diode OLED may be electrically connected to the thin-film transistor TFT through a contact hole defined in the planarization layer 17.

The pixel electrode 21 may include conductive oxide, such as indium tin oxide (“ITO”), indium zinc oxide (“IZO”), ZnO, indium oxide (In₂O₃), indium gallium oxide (“IGO”), or aluminum zinc oxide (“AZO)”. According to an embodiment, the pixel electrode 21 may include a reflective layer including Ag, Mg, Al, Pt, Pd, Au, Ni, Nd, Ir, Cr, or a compound thereof. Alternatively, the pixel electrode 21 may further include a layer including ITO, IZO, ZnO, or In₂O₃, above/below the reflective layer described above.

A pixel-defining layer 19, through which an opening 190P exposing at least a portion of the pixel electrode 21 is defined, may be arranged or disposed on the pixel electrode 21. The pixel-defining layer 19 may include an organic insulating material and/or an inorganic insulating material. The opening 190P may define an emission area of light emitted from the organic light-emitting diode OLED. In an embodiment, for example, a size/width of the opening 190P may correspond to a size/width of the emission area. Thus, a size and/or a width of a pixel PX may be determined based on the size and/or the width of the opening 190P of the pixel-defining layer 19 corresponding to the pixel PX.

The emission layer 22 may be arranged or disposed in the opening 190P of the pixel-defining layer 19. The emission layer 22 may include a high molecular-weight organic material or a low molecular-weight organic material emitting certain color light. Alternatively, the emission layer 22 may include an inorganic emission material or quantum dots.

Although not shown, a first functional layer and a second functional layer may be respectively arranged below and above the emission layer 22. The first functional layer may include, for example, a hole transport layer (“HTL”), or an HTL and a hole injection layer (“HIL”). The second functional layer may include an electron transport layer (“ETL”) and/or an electron injection layer (“EIL”). However, one or more embodiments are not limited thereto. The first functional layer and the second functional layer may be selectively arranged above and below the emission layer 22, respectively.

The first functional layer and/or the second functional layer may be (a) common layer(s) disposed to entirely cover the first substrate 10, like the common electrode 23 to be described below.

The common electrode 23 may be arranged or disposed on the pixel electrode 21 and may overlap the pixel electrode 21. The common electrode 23 may include a conductive material having a low work function. In an embodiment, for example, the common electrode 23 may include a (semi) transparent layer including Ag, Mg, Al, Pt, Pd, Au, Ni, Nd, Ir, Cr, Li, Ca, or an alloy thereof. Alternatively, the common electrode 23 may further include a layer, such as ITO, IZO, ZnO, or In₂O₃, on the (semi) transparent layer including the materials described above. The common electrode 23 may be integrally formed to entirely cover the substrate 10.

An encapsulation member may be arranged or disposed on the display element layer DEL. According to an embodiment, the encapsulation member may be provided as the thin-film encapsulation layer TFE. The thin-film encapsulation layer TFE may be arranged on the display element layer DEL and may cover the display element layer DEL. The thin-film encapsulation layer TFE may include at least one inorganic layer and at least one organic layer. According to an embodiment, the thin-film encapsulation layer TFE may include a first inorganic layer 31, an organic layer 32, and a second inorganic layer 33 that are sequentially stacked. Although not shown, the encapsulation member may be provided as an encapsulation substrate.

The first inorganic layer 31 and the second inorganic layer 33 may include at least one inorganic material selected from aluminum oxide, titanium oxide, tantalum oxide, hafnium oxide, ZnO, SiOₓ, SiNₓ, and SiON. The organic layer 32 may include a polymer-based material. The polymer-based material may include acryl-based resins, epoxy-based resins, polyimide, polyethylene, etc. According to an embodiment, the organic layer 32 may include acrylate. The organic layer 32 may be provided by curing a monomer or applying a polymer.

The touch electrode layer TEL including touch electrodes may be arranged or disposed on the thin-film encapsulation layer TFE, and the optical functional layer OFL may be arranged on the touch electrode layer TEL. The touch electrode layer TEL may obtain coordinate information corresponding to an external input, for example, a touch event. The optical function layer OFL may reduce a reflectivity of light (external light) incident from the outside toward the display apparatus 1 and improve the color purity of light emitted from the display apparatus 1.

According to an embodiment, the optical functional layer OFL may include a phase retarder and/or a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a certain shape of arrangement. The phase retarder and the polarizer may further include a protective film.

According to an embodiment, the optical functional layer OFL may include a destructive interference structure. The destructive interference structure may include a first reflective layer and a second reflective layer disposed in different layers from each other. First reflective light and second reflective light reflected from the first reflective layer and the second reflective layer, respectively, may destructively interfere, and thus, the reflectivity of external light may be decreased.

An adhesion member may be arranged between the touch electrode layer TEL and the optical functional layer OFL. The adhesion member may not be limited to particular types and may be implemented as general members known in the art. In an embodiment, for example, the adhesion member may include a pressure sensitive adhesive (“PSA”).

The cover window CW may be arranged on the display panel DP. The cover window CW may adhere to the display panel DP by using an adhesion member. The adhesion member may include, for example, a PSA.

The cover window CW may have high transmittance to transmit light emitted from the display panel DP and little thickness to minimize the weight of the display apparatus 1. Also, the cover window CW may have great rigidity and hardness to protect the display panel DP from external shocks. The cover window CW may include, for example, glass or plastic. According to an embodiment, the cover window CW may include ultra-thin hardened glass having the rigidity strengthened through chemical tempering or thermal tempering.

In an embodiment, as described above, the display apparatus 1 includes the organic light-emitting diode OLED as the light-emitting element. However, the display apparatus 1 according to one or more embodiments is not limited thereto. According to an alternative embodiment, the display apparatus 1 may include an inorganic light-emitting display apparatus or an inorganic electroluminescent (“EL”) display apparatus including an inorganic light-emitting diode. The inorganic light-emitting diode may include a PN junction diode including inorganic semiconductor-based materials. When a voltage is applied to the PN junction diode in a normal direction, holes and electrons may be injected into the PN junction diode, and energy generated by recombination of holes and the electrons may be converted into light energy to emit a certain color of light. The inorganic light-emitting diode described above may have a width of several to hundreds of micrometers, and according to an embodiment, the inorganic light-emitting diode may be referred to as a micro light-emitting diode.

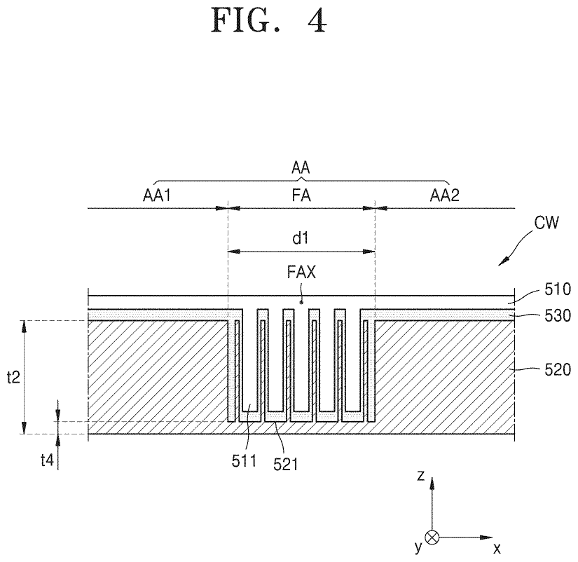

FIG. 4 is a cross-sectional view of the cover window CW according to an embodiment.

Referring to FIG. 4, an embodiment of the cover window CW may include a folding portion FA and a peripheral portion AA. The folding portion FA may be an area folded with respect to the folding axis FAX (see FIGS. 1 and 2), and the peripheral portion AA may be an area continually connected to the folding portion FA and extending from the folding portion FA. The cover window CW may be in-folded or out-folded with respect to the folding axis FAX. Here, in-folding may denote folding of the cover window CW in a +z direction with respect to the folding axis FAX, and out-folding may denote folding of the cover window CW in a −z direction with respect to the folding axis FAX. The peripheral portion AA may include a first peripheral portion AA1 connected to a side (for example, a side in a −x direction of FIG. 4) with respect to the folding portion FA and a second peripheral portion AA2 connected to the other side (for example, a side in a +x direction of FIG. 4) with respect to the folding portion FA, where the other side is opposite to the side.

According to an embodiment, the cover window CW may include a first layer 510 and a second layer 520 that are sequentially stacked.

The first layer 510 may be a film layer. According to an embodiment, the first layer 510 may include polyimide. The second layer 520 may be arranged between the first layer 510 and the display panel 10. According to an embodiment, the second layer 520 may include a glass layer and may include, for example, ultra-thin glass (“UTG”). However, one or more embodiments are not limited thereto. As described above, the first layer 510 and the second layer 520 may include different materials from each other. Thus, in such an embodiment, the cover window CW may be flexible due to the film layer and may have enhanced shock resistance due to the glass layer.

The first layer 510 and the second layer 520 may form or define a pattern. According to an embodiment, the pattern of the first layer 510 and the second layer 520 may be formed or defined only in the folding portion FA. According to an alternative embodiment, the pattern of the first layer 510 and the second layer 520 may be formed or defined throughout the cover window CW, rather than only in the folding portion FA. Hereinafter, for convenience of description, embodiments in which the pattern is formed only in the folding portion FA will be mainly described.

According to an embodiment, the pattern of the first layer 510 may include a projection portion 511. In such an embodiment, the projection portion 511 may be provided, for example, on a surface of the first layer 510, where the surface faces the second layer 520. According to an embodiment, the projection portion 511 may be provided in plural, and the projection portions 511 are apart from each other in a first direction (for example, an x direction of FIG. 4). In an embodiment, the projection portion 511 may extend in a second direction (for example, a y direction of FIG. 4) crossing the first direction. Here, the projection portion 511 may continually extend in parallel with the folding axis FAX or may include a plurality of projection portions arranged in parallel with the folding axis FAX to be apart from each other. Hereinafter, for convenience of description, an embodiment in which the projection portion 511 continually extends in parallel with the folding axis FAX will be mainly described.

According to an embodiment, a length d1 of an area of the first layer 510, in which the plurality of projection portions 511 are arranged, for example, the length d1 in a direction (the x direction of FIG. 4) vertical to the folding axis FAX, may be greater than πR. Here, R denotes a radius of curvature R of the folding portion FA when the folding portion FA is folded. Accordingly, the plurality of projection portions 511 may reduce stress throughout the folding portion FA when the folding portion FA is bent.

The projection portion 511 may have a cross-section having a rectangular shape, when viewed vertically with respect to the folding axis FAX. However, the projection portion 511 is not limited thereto and may have a cross-section having a triangular or circular shape. That is, trenches may be formed in the projection portion 511.

Also, according to an embodiment, a projection length (for example, a length in a z direction of FIG. 4) of the projection portion 511 may be greater than a width (for example, a length in the x direction of FIG. 4) of the projection portion 511.

According to an embodiment, the pattern of the second layer 520 may include an accommodation portion 521. The accommodation portion 521 may have a shape concave toward an inner portion of the second layer 520, and the projection portion 511 may be accommodated in the concave shape of the accommodation portion 521. In an embodiment, as described above, where the projection portion 511 includes a plurality of projection portions, the accommodation portion 521 may also include a plurality of accommodation portions, the number of which corresponds to the number of projection portions, to accommodate the projection portion 511. In such an embodiment, the accommodation portion 521 may be provided to have a shape corresponding to a shape of the projection portion 511. In an embodiment, for example, where the projection portion 511 has a rectangular shape, the accommodation portion 521 may have a bigger rectangular shape than the projection portion 511. Accordingly, as illustrated in FIG. 4, the plurality of projection portions 511 and the plurality of accommodation portions 521 may be arranged to interlock with each other. This structure may reduce the stress applied to the cover window CW, when the cover window CW is bent or folded.

According to an embodiment, the projection length (a length in a −z direction of FIG. 4) of the projection portion 511 may be less than a thickness (a length in the z direction of FIG. 4) of the second layer 520. That is, the projection portion 511 may project toward the inside of the second layer 520 and may not penetrate the second layer 520. Thus, the second layer 520 may have a thickness t4 in an area thereof for accommodating the projection portion 511, and the thickness t4 may be less than a thickness t2 of the second layer 520. According to an embodiment, the thickness t4 may be less than or equal to a half of the thickness t2 of the second layer 520.

In an embodiment, the projection portion 511 and the accommodation portion 521 may interlock with each other or join together with a distance therebetween. In an embodiment, an inner (or a lowermost) surface of the projection portion 511 and an inner surface of the accommodation portion 521 may be apart from each other by a predetermined distance. According to an embodiment, a resin 530 may be filled in a space between the outer surface of the projection portion 511 and the inner surface of the accommodation portion 521 by the predetermined distance. According to an embodiment, the resin 530 may include an acryl-based material, a silicon-based material, a urethane-based material, or a phenol-based material. The resin 530 may fill the gap between the projection portion 511 and the accommodation portion 521 as described above and may have a relatively less modulus, and thus, the cover window CW may have bending flexibility. In an embodiment, the resin 530 may be arranged or disposed between the first layer 510 and the second layer 520 and may adhere the first layer 510 and the second layer 520 to each other.

According to an embodiment, the first layer 510, the second layer 520, and the resin 530 may have a same refractive index as one another. IN such an embodiment, a material of the resin 530 may be selected in a way such that the refractive index of the resin 530 may be substantially the same as the refractive index of the first layer 510 and the second layer 520. Accordingly, visibility reduction, which may be caused by a difference in refractive index among the first and second layers 510 and 520, which may include heterogeneous materials from each other, and the resin 530, may be effectively prevented.

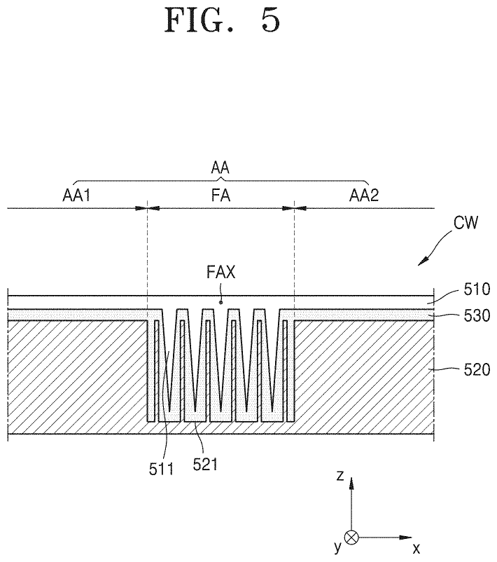

FIG. 5 is a cross-sectional view of the cover window CW according to an embodiment.

Referring to FIG. 5, the projection portion 511 may have a shape that is tapered in a projection direction (for example, a −z direction of FIG. 5). According to an embodiment, the projection portion 511 may have a triangular shape when viewed vertically with respect to the folding axis FAX. Here, the accommodation portion 521 may maintain the described shape, for example, the rectangular shape. Thus, distances between the projection portion 511 and the accommodation portion 521 may be different with respect to the projection direction of the projection portion 511. In such an embodiment, as described above, the resin 530 may be filled between the projection portion 511 and the accommodation portion 521. Because the resin 530 having a less modulus is filled in the folding portion FA that is frequently bent and between the projection portion 511 and the accommodation portion 521, stress may be reduced when the cover window CW is folded or bent.

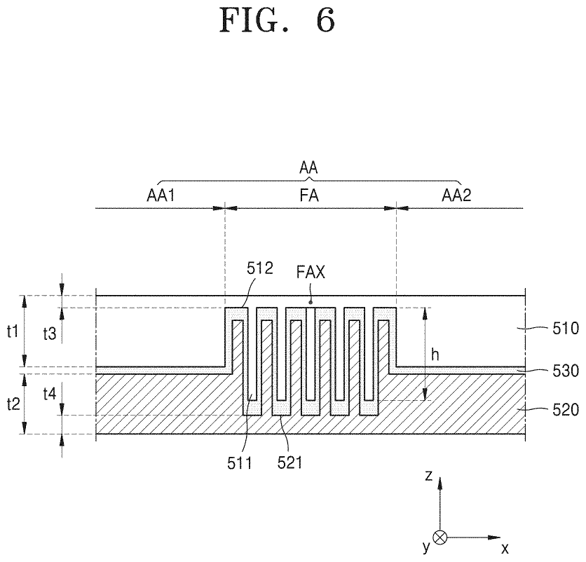

FIG. 6 is a cross-sectional view of the cover window CW according to an embodiment. Hereinafter, for convenience of description, different features of the embodiment of the cover window of FIG. 6 from those of the embodiments described above will be described in detail.

Referring to FIG. 6, in an embodiment, the pattern of the first layer 510 may include the projection portion 511 and a concave portion 512. In such an embodiment, the first layer 510 may include the concave portion 512 that is concave toward an inner portion of the folding portion FA. The projection portion 511 may project from the concave portion 512 toward the second layer 520, e.g., toward the accommodation portion 521. The projection portion 511 may have a rectangular shape, when viewed vertically with respect to the folding axis FAX, as described above. Alternatively, although not shown in FIG. 6, the projection portion 511 may have a triangular shape, as described above.

In an embodiment, a thickness of the first layer 510 may be different between an area of the first layer 510, in which the projection portion 511 is arranged, and an area of the first layer 510, in which the projection portion 511 is not arranged. In such an embodiment, a thickness t3 of the area of the first layer 510, in which the projection portion 511 is arranged, may be less than a thickness t1 of the area of the first layer 510, in which the projection portion 511 is not arranged.

According to an embodiment, a height (or the projection length) h of at least one of the plurality of projection portions 511 may be greater than the thickness t1 of the first layer 510. Accordingly, the projection portion 511 may project from the concave portion 512 by a length greater than the thickness t1 of the first layer 510 to project into an area corresponding to a thickness t2 of the second layer 520.

In such an embodiment, the accommodation portion 521 of the second layer 520 may have a pattern to interlock with the projection portion 511. In such an embodiment, the accommodation portion 521 may include a portion projecting by a length that is greater than the thickness t2 of the second layer 520, and the projecting portion may be arranged in the inner portion of the first layer 510 to surround the projection portion 511. Here, the first layer 510 and the second layer 520 may have similar patterns as each other.

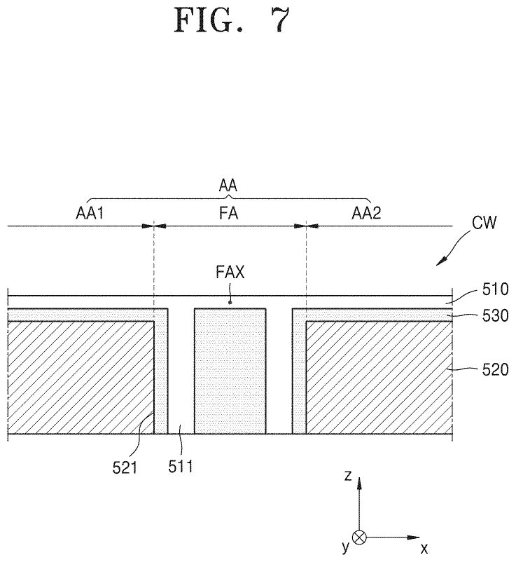

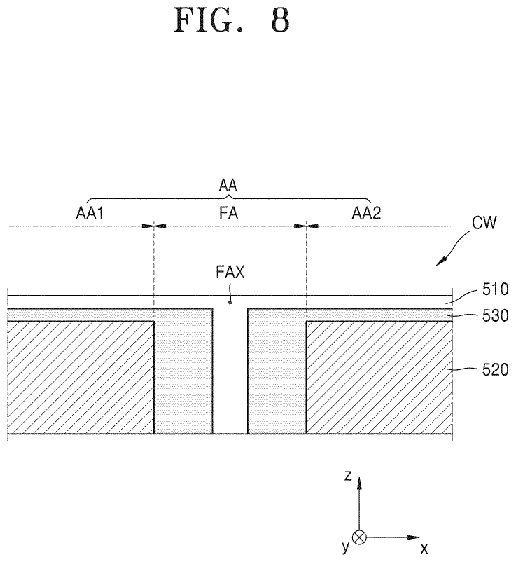

FIGS. 7 and 8 are cross-sectional views of the cover window CW according to an embodiment. Hereinafter, for convenience of description, different features of the embodiments of the cover window of FIGS. 7 and 8 from those of the embodiments described above will be described in detail.

Referring to FIG. 7, in an embodiment, the accommodation portion 521 of the second layer 520 may be penetrated by the projection portion 511. In such an embodiment, the projection portion 511 may penetrate or be disposed through the second layer 520 to project up to a plane that is the same as a surface (for example, a surface in a −z direction of FIG. 7) of the second layer 520. According to an embodiment, the projection portion 511 may be provided in plural, and the plurality of projection portions 511 may be accommodated in one accommodation portion 521. FIG. 7 illustrates an embodiment including only two projection portions 511. Alternatively, the projection portion 511 may include more than two projection portions 511.

In an embodiment, the resin 530 may be arranged in a space between the projection portion 511 and the accommodation portion 521, and thus, the resin 530 may be filled between the plurality of projection portions 511.

According to an embodiment, one accommodation portion 521 may be provided to have a size corresponding to an area of the folding portion FA. In such an embodiment, the accommodation portion 521 may be provided to cover all of folded areas of the cover window CW. Thus, the projection portion 511 and the resin 530 may adhere to each other in the folding portion FA, and stress of the folding portion FA may be alleviated.

Referring to FIG. 8, according to an alternative embodiment, the projection portion 511 may include a single projection portion, and a single accommodation portion 521 may accommodate the projection portion 511. In such an embodiment, the projection portion 511 may be arranged on the folding axis FAX.

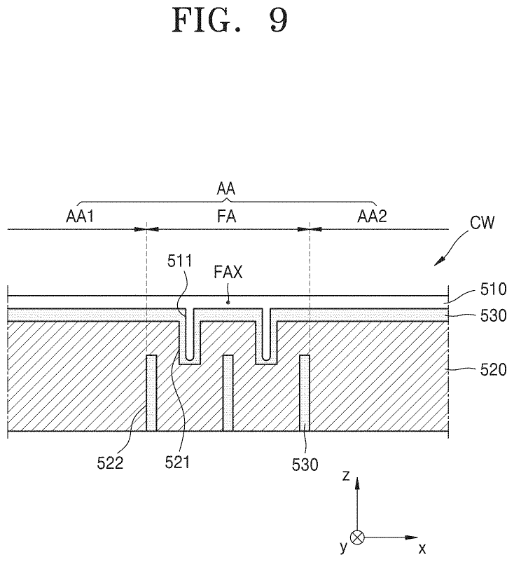

FIGS. 9 through 11 are cross-sectional views of the cover window CW according to an alternative embodiment.

Referring to FIGS. 9 through 11, according to an embodiment, the second layer 520 may include a groove 522 in a surface thereof that is opposite to a surface thereof for accommodating the projection portion 511. In such an embodiment, at least one groove 522 may be arranged, and the groove 522 may be arranged between the plurality of projection portions 511.

The groove 522 may extend from a surface (for example, a surface in a −z direction of FIG. 9) of the second layer 520 toward the other surface of the second layer 520. Here, a depth (a length in a +z direction of FIG. 9) of the groove 522 may be defined to partially overlap the accommodation portion 521, when viewed from a direction (for example, a direction in an x direction of FIG. 9).

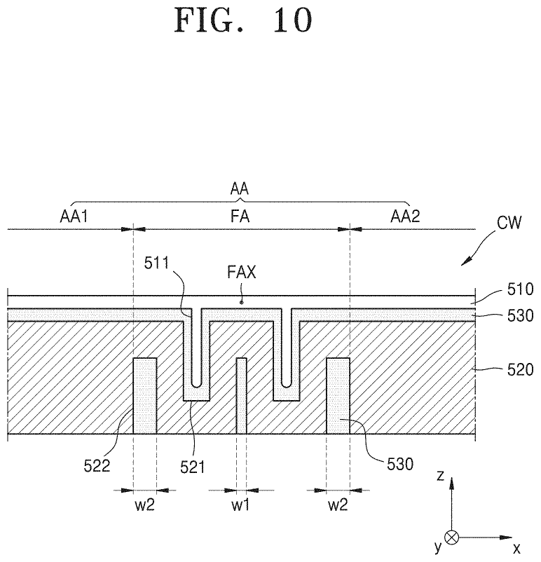

In an embodiment, where the plurality of grooves 522 are arranged, a width w1 (for example, a length in an x direction of FIG. 10) of at least one groove 522 may be different from widths w2 of the other grooves 522, as illustrated in FIG. 10. Referring to FIG. 10, the plurality of grooves 522 may be symmetrically arranged at opposing sides of the folding axis FAX. FIG. 10 illustrates an embodiment where one groove 522 is arranged at the center, and other grooves 522 are symmetrically arranged at both sides of the groove 522 at the center. In such an embodiment, the widths w2 of the grooves 522 at the opposing sides may be greater than the width w1 of the groove 522 at the center. However, it is not limited thereto, and the grooves 522 may have a same width was illustrated in FIG. 9, or the width w1 of the groove 522 at the center may be greater than the widths w2 of the grooves 522 at the opposing sides.

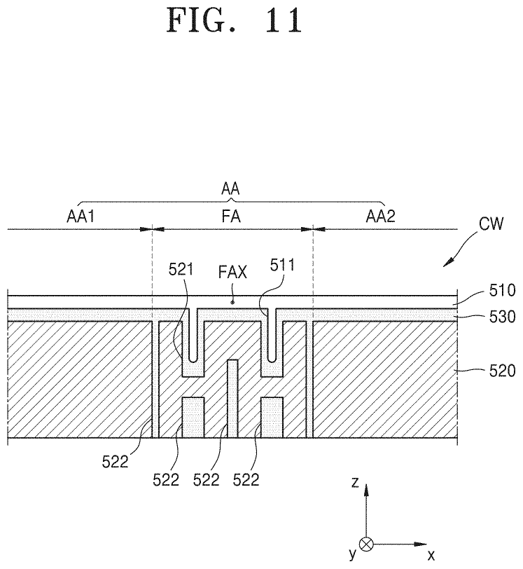

Referring to FIG. 11, according to an embodiment, some of the plurality of grooves 522 may be arranged between the plurality of projection portions 511, and others of the plurality of grooves 522 may be arranged to face the plurality of projection portions 511 in a direction (for example, a z direction of FIG. 11). Further, yet others of the plurality of grooves 522 may be provided to be apart from the projection portion 511 in a direction (for example, an x or a −x direction of FIG. 11) toward the peripheral portion AA and to penetrate the second layer 520.

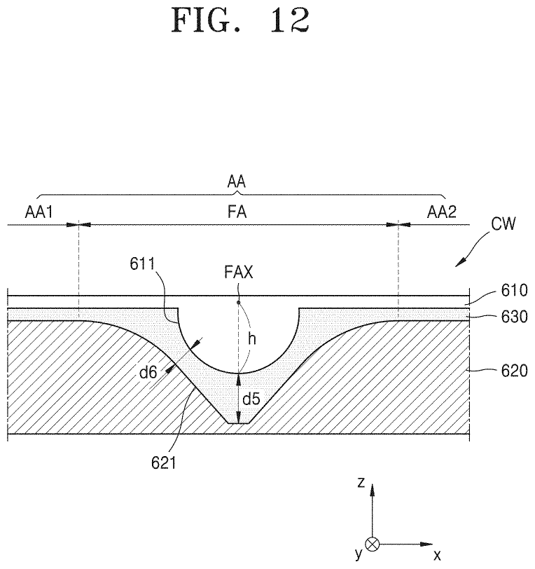

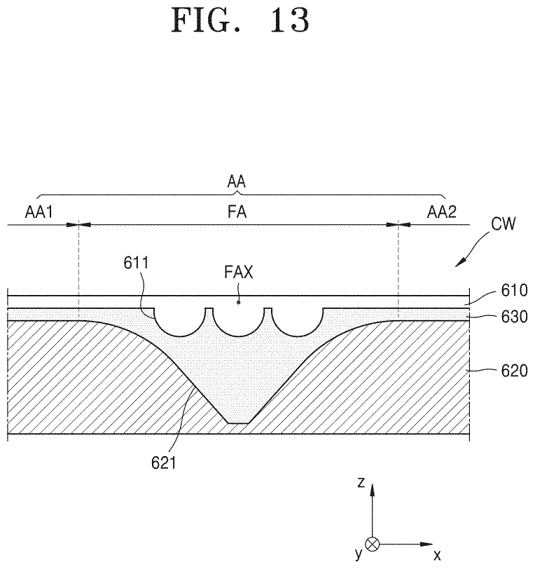

FIGS. 12 and 13 are cross-sectional views of the cover window CW according to an alternative embodiment. Hereinafter, for convenience of description, different features of the embodiments of the cover window of FIGS. 12 and 13 from those of the embodiments described above will be described in detail.

Referring to FIG. 12, in an embodiment, a projection portion 611 of a first layer 610 may have a greatest projection length h (a length in the −z direction of FIG. 9) at the center of the folding portion FA, that is, at a point crossing the folding axis FAX, and may have a decreased projection length toward the peripheral portion AA. In such an embodiment, the projection portion 611 of the first layer 610 may include a curved surface. When viewed vertically with respect to the folding axis FAX, the projection portion 611 may have a circular or semi-circular cross-section. In an embodiment, a single projection portion 611 may be provided as illustrated in FIG. 12. Alternatively, a plurality of projection portions 611 may be provided as illustrated in FIG. 13. Hereinafter, an embodiment in which a single projection portion 611 is provided as illustrated in FIG. 12 will be mainly described.

An accommodation portion 621 that accommodates the projection portion 611 may not be formed to have a shape corresponding to a shape of the projection portion 611. In an embodiment, for example, where the projection portion 611 has a semi-circular cross-section, the accommodation portion 621 may not necessarily have to have a semi-circular cross-section. The accommodation portion 621 may include a curved surface as illustrated in FIG. 12, but is not limited thereto.

According to an embodiment, distances between an outer surface of the projection portion 611 and an inner surface of the accommodation portion 621 may be different from each other, according to predetermined points of the outer surface of the projection portion 611. Here, the distances between the outer surface of the projection portion 611 and the inner surface of the accommodation portion 621 may be lengths between the outer surface of the projection portion 611 and the inner surface of the accommodation portion 621 meeting a straight line crossing the folding axis FAX.

As illustrated in FIG. 12, a distance d5 between a first point of the lower surface of the projection portion 611 and the inner surface of the accommodation portion 621 and a distance d6 between a second point of the outer surface of the projection portion 611 and the inner surface of the accommodation portion 621 may be different from each other. According to an embodiment, a distance between the outer surface of the projection portion 611 and the inner surface of the accommodation portion 621 may have the greatest value at the center of the folding portion FA, that is, based on a point of the outer surface of the projection portion 611, where the point is vertical (a −z direction of FIG. 12) to the folding axis FAX. Accordingly, a resin 630 having a less modulus may be thickly disposed at a region where the most stress may occur when the cover window CW is folded, and the second layer 620 may have a reduced thickness, thereby alleviating the stress when the cover window CW is folded.

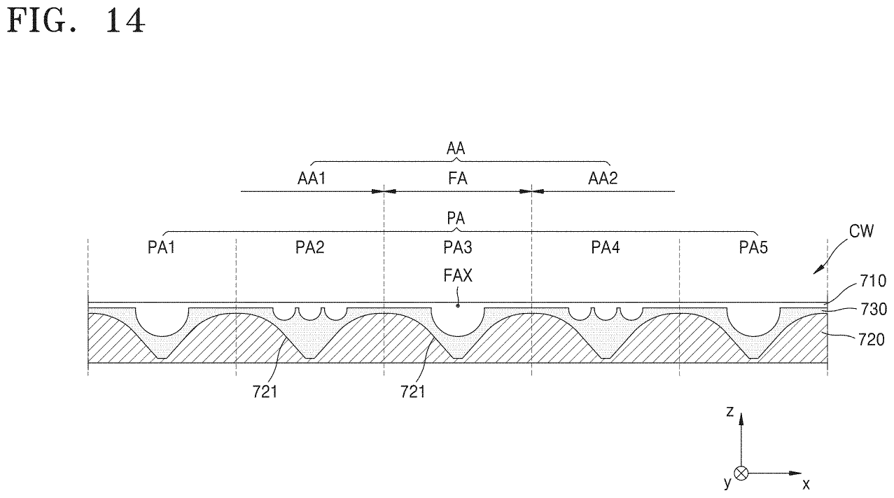

FIGS. 14 through 16 are cross-sectional views of a cover window according to another alternative embodiment. Hereinafter, for convenience of description, different features of the embodiments of the cover window of FIGS. 14 through 16 from those of the embodiments described above will be described in detail.

Referring to FIGS. 14 through 16, in an embodiment, a plurality of pattern areas PA may be arranged in a first layer 710 or 810. According to an embodiment, a resin 730 or 830 may be filled in a space between an outer surface of a projection portion of the first layer 710 or 810 and an inner surface of an accommodation portion of the second layer 720 or 820 by a predetermined distance. FIGS. 14 through 16 illustrate an embodiment where the pattern areas PA include a first pattern area PA1 through a fifth pattern area PA5. However, the pattern areas PA are not limited thereto.

According to an embodiment, some of the plurality of pattern areas PA may be arranged in the folding portion FA, and the others of the plurality of pattern areas PA may be arranged in the peripheral area AA adjacent to the folding portion FA. In an embodiment, for example, the third pattern area PA3 may be arranged in the folding portion FA, the first pattern area PA1 and the second pattern area PA2 may be arranged in the first peripheral portion AA1, and the third pattern area PA3 and the fourth pattern area PA4 may be arranged in the second peripheral portion AA2.

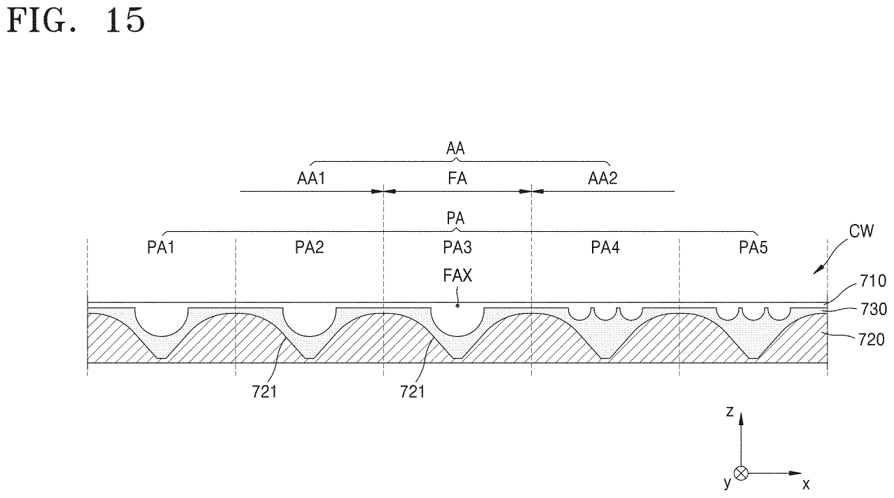

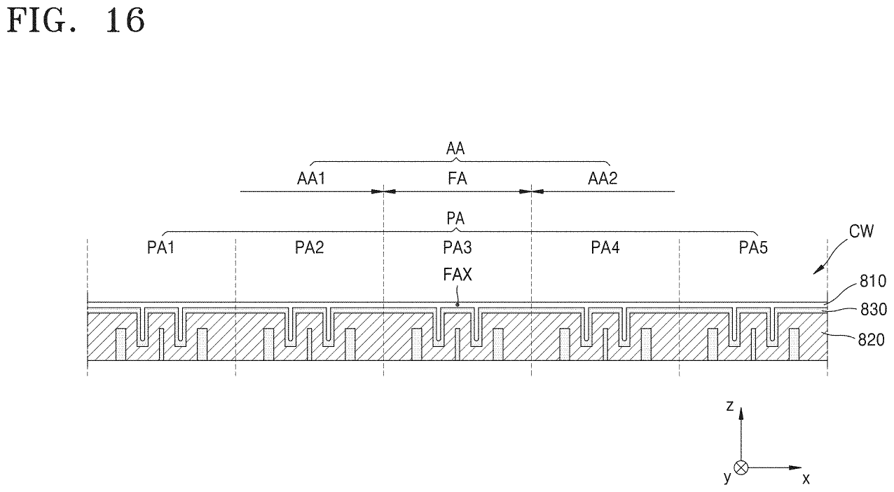

In an embodiment, as shown in FIGS. 14 and 15, in each pattern area PA, one of various patterns including the projection portions 511 and 611 of the first layers 510 and 610 described above and one of various patterns including the accommodation portions 521 and 621 of the second layers 520 and 620 described above may be arranged. In such an embodiment, one pattern area PA may include a combination of one of various patterns including the projection portions 511 and 611 described above as a projection portion of the first layer 710 and one of various patterns including the accommodation portions 521 and 621 described above as an accommodation portion 721 of the second layer 720. According to an embodiment, the pattern of each pattern area PA may be the same as each other as illustrated in FIG. 16 or may be different from each other as illustrated in FIGS. 14 and 15. In an embodiment, for example, as illustrated in FIG. 14, the patterns of the first pattern area PA1 and the third pattern area PA3 may be the same as each other, and the patterns of the second pattern area PA2 and the fourth pattern area PA4 may be the same as each other. Alternatively, as illustrated in FIG. 15, the patterns of the first pattern area PA1 through the third pattern area PA3 may be the same as each other, and the patterns of the fourth pattern area PA4 and the fifth pattern area PA5 may be the same as each other.

According to an embodiment, the patterns arranged in the plurality of pattern areas PA may be symmetrically arranged with respect to the folding axis FAX. In an embodiment, for example, with respect to the pattern of the third pattern area PA arranged in the folding axis FAX, the patterns of the first pattern area PA1 and the fifth pattern area PA5 may be the same as each other, and the patterns of the second pattern area PA2 and the fourth pattern area PA4 may be the same as each other.

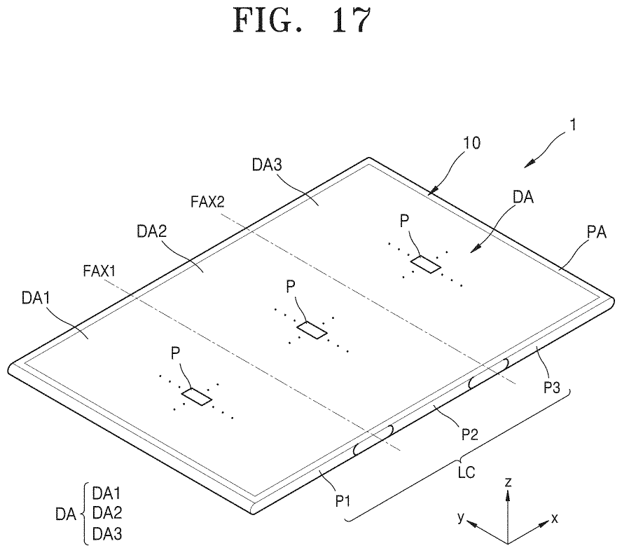

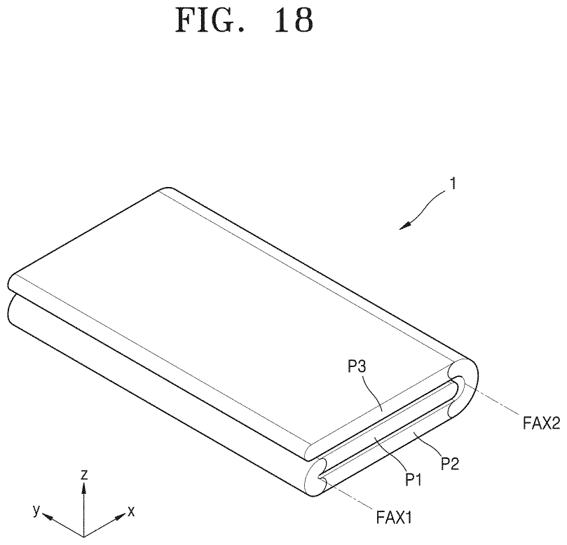

FIGS. 17 and 18 are perspective views of the display apparatus 1 according to another alternative embodiment. Hereinafter, for convenience of description, different features of the embodiments of the cover window of FIGS. 17 and 18 from those of the embodiments described above will be described in detail.

According to an embodiment, the display panel 10 may be a flexible display panel that is easily bent, folded, or rolled based on its flexibility. In an embodiment, for example, the display panel 10 may include a foldable display panel, which may be folded or unfolded, a curved display panel having a curved display surface, a bent display panel, in which areas except for a display surface are bent, a rollable display panel, which may be rolled or unrolled, or a stretchable display panel, which may be stretched.

According to an embodiment, the display panel 10 may include a first folding axis FAX1 and a second folding axis FAX2. The display panel 10 may be folded with respect to the first folding axis FAX1 and the second folding axis FAX2.

A first display area DA1 and a second display area DA2 may be defined with the first folding axis FAX1 therebetween. In such an embodiment, the second display area DA2 and a third display area DA3 may be defined with the second folding axis FAX2 therebetween.

The lower cover LC may form or define an exterior shape of a lower surface of the display apparatus 1. The lower cover LC may include plastic, metal, or both of plastic and metal. The lower cover LC may include a first portion P1, a second portion P2, and a third portion P3 supporting the display panel 10. The lower cover LC may be folded with respect to the first folding axis FAX1 between the first portion P1 and the second portion P2. In such an embodiment, the lower cover LC may be folded with respect to the second folding axis FAX2 between the second portion P2 and the third portion P3.

According to an embodiment, the first display area DA1 and the second display area DA2 may be in-folded with respect to the first folding axis FAX1 to face each other. The second display area DA2 and the third display area DA3 may be folded with respect to the second folding axis FAX2 to face each other. Here, after the first display area DA1 is folded to face the second display area DA2, the third display area DA3 may be folded to face the second display area DA2. That is, the third display area DA3 may be folded to face a rear surface of the first display area DA1 that is already folded, in detail, a first portion P1 of the first display area DA1.

According to an alternative embodiment, each of the first and second display areas DA1 and DA2 and the second and third display areas DA2 and DA3 may be out-folded not to face each other. That is, the first portion P1 and a second portion P2 may be folded to face each other with respect to the first folding axis FAX1, and the second portion P2 and a third portion P3 may be folded to face each other with respect to the second folding axis FAX2.

Alternatively, either one of the first and second display areas DA1 and DA2 and the second and third display areas DA2 and DA3 may be in-folded with respect to the folding axis to face each other, and the other may be out-folded with respect to the folding axis not to face each other.

Hereinafter, for convenience of description, embodiments in which both of the first and second display areas DA1 and DA2 and the second and third display areas DA2 and DA3 are folded with respect to the first folding axis FAX1 and the second folding axis FAX2, respectively, to face each other will be mainly described.

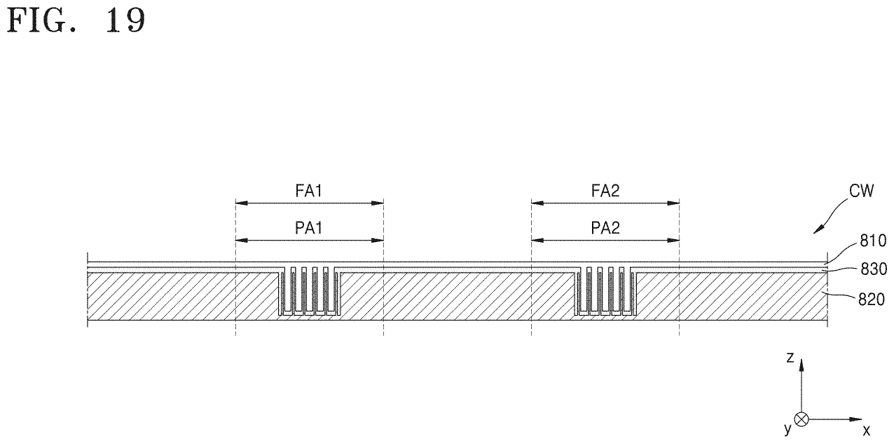

FIGS. 19 through 21 are cross-sectional views of the cover window CW according to another alternative embodiment. Hereinafter, for convenience of description, different features of the embodiments of the cover window of FIGS. 19 through 21 from those of the embodiments described above will be described in detail.

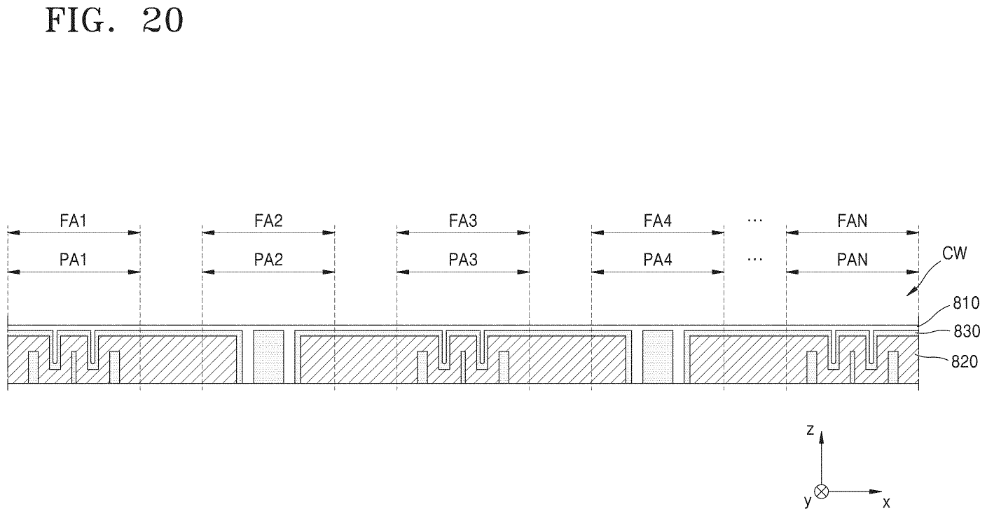

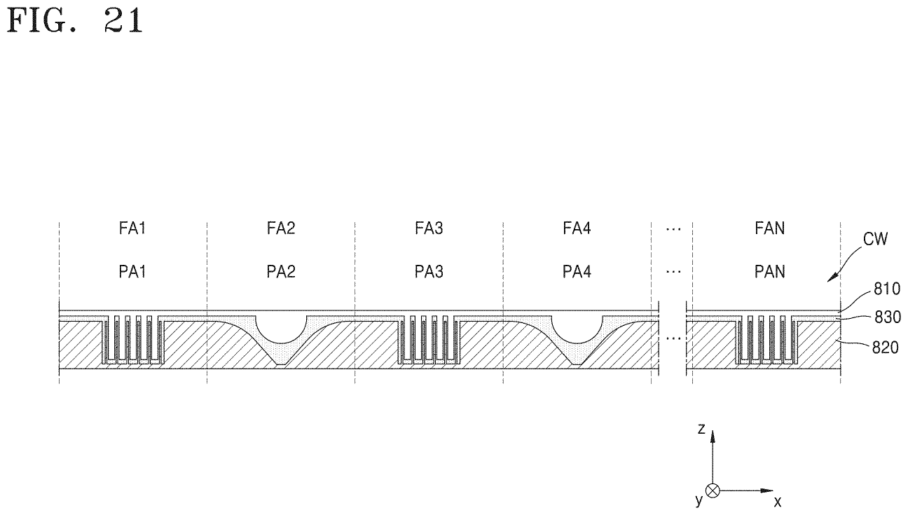

Referring to FIGS. 19 through 21, in an embodiment, the cover window CW may be arranged in the display apparatus 1 described above. In such an embodiment, the plurality of pattern areas PA may be arranged to be apart from each other. In such an embodiment, the folding portion FA may include a plurality of folding portions, for example, two folding portions (FA1 and FA2 shown in FIG. 19) or N folding portions (FA1 to FAN in FIGS. 20 and 21), in a direction (for example, an x direction of FIG. 19), and the plurality of pattern areas PA, for example, two pattern portions (PA1 and PA2 shown in FIG. 19) or N pattern portions (PA1 to PAN in FIGS. 20 and 21), may be arranged to correspond to the plurality of folding portions FA, respectively. Here, N is a natural number. In such an embodiment, patterns of a first layer 810 and a second layer 820 arranged in each of the plurality of pattern areas PA may alleviate the stress in each of the plurality of folding portions FA.

Referring to FIG. 20, in an embodiment of the cover window CW of the display apparatus which is folded or foldable twice or more, the folding portion FA may include more than two folding portions. In such an embodiment, the pattern area PA may be arranged in each folding portion FA, and the pattern areas PA may include the same or different patterns as or from each other.

According to an embodiment, a distance between the plurality of pattern areas PA may be the same as each other. However, it is not limited thereto, and the distance may be different according to a folded region. In an embodiment, the distance between the first pattern area PA1 and the second pattern area PA2 may be less than the distance between the second pattern area PA2 and the third pattern area PA3. However, one or more embodiments are not limited thereto. In an embodiment, for example, the distance between the first pattern area PA1 and the second pattern area PA2 may be greater than the distance between the second pattern area PA2 and the third pattern area PA3.

Also, referring to FIG. 21, in an embodiment of the cover window CW of a rollable display apparatus that is bent in a plurality of portions, the folding portion FA may include a plurality of folding portions FA continually arranged in a direction from a side to the other side of the cover window CW. Each folding portion FA may include the pattern area PA, in which the same or different pattern may be arranged.

In an embodiment, as described above, the display apparatus may alleviate stress when the display apparatus is folded or bent and may realize the increased durability.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a display panel which is foldable with respect to a folding axis; and
a cover window disposed on the display panel, wherein a folding portion and a peripheral portion adjacent to the folding portion are defined in the cover window,
wherein the cover window includes:
a first layer including a plurality of projection portions apart from each other in a first direction;
a second layer partially concave to accommodate the plurality of projection portions and coupled to the projection portions with a gap therebetween; and
a resin filled in the gap.

2. The display apparatus of claim 1, wherein a material included in the first layer is different from a material included in the second layer.

3. The display apparatus of claim 1, wherein the plurality of projection portions is disposed in the folding portion.

4. The display apparatus of claim 1, wherein each of the plurality of projection portions has a width decreasing in a direction.

5. The display apparatus of claim 1, wherein
the folding portion has a radius of curvature when folded, and
a length of an area in which the plurality of projection portions is disposed is greater than π times the radius of curvature.

6. The display apparatus of claim 1, wherein the first layer, the second layer, and the resin have a same refractive index as each other.

7. The display apparatus of claim 1, wherein the plurality of projection portions is disposed through the second layer.

8. The display apparatus of claim 1, wherein a thickness of an area of the second layer, which accommodates the plurality of projection portions, is less than or equal to a half of a thickness of an area of the second layer which does not accommodate the plurality of projection portions.

9. The display apparatus of claim 1, wherein a thickness of an area of the first layer, in which the plurality of projection portions is disposed, is less than a thickness of an area of the first layer, in which the plurality of projection portions is not disposed.

10. The display apparatus of claim 1, wherein
the first layer further includes a concave portion, and
the plurality of projection portions project from the concave portion.

11. The display apparatus of claim 10, wherein a height of at least one selected from the plurality of projection portions is greater than a thickness of the first layer.

12. The display apparatus of claim 1, wherein the plurality of projection portions is disposed to interlock with the second layer.

13. The display apparatus of claim 1, wherein
the second layer further includes an accommodation portion which accommodates the plurality of projection portions, and
the gap varies between the projection portions and the accommodation portion.

14. The display apparatus of claim 1, wherein the plurality of projection portions is accommodated in a single accommodation portion.

15. The display apparatus of claim 14, wherein the resin is disposed in a space between the plurality of projection portions.

16. The display apparatus of claim 1, wherein the second layer includes a groove in a surface opposite to a surface on which the plurality of projection portions is disposed.

17. The display apparatus of claim 16, wherein the groove is disposed between the plurality of projection portions.

18. The display apparatus of claim 16, wherein
the groove are provided in plural, and
a width of one of a plurality of grooves is different from a width of another of the plurality of grooves.

19. The display apparatus of claim 16, wherein
the groove is provided in plural, and
a plurality of grooves is symmetrical with respect to the folding axis.

20. A display apparatus comprising:
a display panel which is foldable with respect to a folding axis; and
a cover window disposed on the display panel, wherein a folding portion and a peripheral portion adjacent to the folding portion are defined in the cover window,
wherein the cover window includes:
a first layer including a projection portion projecting in a direction; and
a second layer including an accommodation portion which accommodates the projection portion, and
wherein a distance between an outer surface of the projection portion and an inner surface of the accommodation portion in a direction vertical to the outer surface of the projection portion varies along the outer surface of the projection portion.

21. The display apparatus of claim 20, wherein a resin is disposed between the projection portion and the accommodation portion.

22. The display apparatus of claim 20, wherein the distance has a greatest value at a center of the projection portion.

23. The display apparatus of claim 20, wherein the projection portion has a semi-circular cross-section when viewed vertically with respect to the folding axis.

24. A display apparatus comprising:
a display panel that is foldable with respect to a folding axis; and
a cover window disposed on the display panel, wherein a folding portion and a peripheral portion adjacent to the folding portion are defined in the cover window,
wherein the cover window includes:
a first layer including a plurality of projection patterns; and
a second layer including a plurality of accommodation patterns which accommodates the plurality of projection patterns.

25. The display apparatus of claim 24, wherein one of the plurality of projection patterns or one of the plurality of accommodation patterns is different from another of the plurality of projection patterns or another of the plurality of accommodation patterns.

26. The display apparatus of claim 24, wherein the plurality of projection patterns and the plurality of accommodation patterns are disposed in the folding portion and the peripheral portion adjacent to the folding portion.

27. The display apparatus of claim 24, wherein
the folding portion is provided in plural,
a plurality of folding portions is disposed in a way such that the plurality of folding portions are apart from each other in a direction, and
each of the plurality of projection patterns and each of the plurality of accommodation patterns are disposed in each of the plurality of folding portions.
